(19) United States
(12) Patent Application Publication
(10) Pub. No.: US 2006/0189171 A1
(43) Pub. Date: Aug. 24, 2006

(54) Seasoning process for a deposition chamber

(76) Inventors: Choon Ann Chua, Singapore (SG); Lee Hong Kang, Singapore (SG); Chee Jau Foo, Singapore (SG)

Correspondence Address: CHRISTIE, PARKER & HALE, LLP, PO BOX 7068, PASADENA, CA, 91109-7068, US

(21) Appl. No.: 11/064,427

(22) Filed: Feb. 23, 2005

(51) Int. Cl. H01L 21/00; H01L 21/31

(52) U.S. Cl. 438/800; 438/905; 438/787

(57) ABSTRACT

A seasoning process for a deposition chamber, the process comprising providing a silicon-containing seasoning gas inside the deposition chamber; and forming a silicon-based seasoning film on at least one surface inside the deposition chamber, the seasoning film having a refractive index of about 1.48 or more.

### FIELD OF INVENTION

The present invention relates broadly to a seasoning process for a deposition chamber and to a method of processing a wafer in deposition chamber.

### BACKGROUND

With the increasing demand for high voltage transistor applications, and especially for flash products, keeping the level of metallic contamination low during the processing of such devices is crucial.

During the manufacturing of such devices, it has been noted that the deposition chamber, e.g. a High Density Plasma Chemical Vapour Deposition (HDPCVD) chamber used for typical Chemical Vapour Deposition (CVD) processes, may be a contributing source to aluminium (Al) contamination. This may typically be due to poor hardware quality of the HDPCVD chamber as well as insufficient protection from the post-cleaning seasoning of the chamber.

In a typical HDPCVD chamber that may be contributing to Al contamination, it has been noted that Al contamination for e.g. as deposited Shallow Trench Isolated (STI) oxide films was significant. It may be about 30E10 atoms/cm². The additional Al atoms may contribute to failure in the P⁺ in High-voltage N-well (HN-well) Wafer Acceptance Test (WAT) test structures.

The effect of the Al contaminant may be the formation of interface traps at the trench sidewalls during deposition of STI oxide films. This may have the effect of enhancing the junction leakage current since the HN-well ions are attracted towards the traps containing Al ions. Due to this effect, the breakdown voltage of the high-voltage (HV) transistors may have been lowered due to a lowered requirement of voltage to induce current flow. Decrement of breakdown voltages of HV transistors in flash products is undesirable.

### SUMMARY

In accordance with a first aspect of the present invention there is provided a seasoning process for a deposition chamber, the process comprising providing a silicon-containing seasoning gas inside the deposition chamber; and forming a silicon-based seasoning film on at least one surface inside the deposition chamber, the seasoning film having a refractive index of about 1.48 or more.

The seasoning film may have a refractive index of about 1.49 or more.

The method may comprise utilising a O₂:SiH₄ gas ratio of about 1.60 or less during the formation of the seasoning film.

The O₂:SiH₄ gas ratio may be about 1.50 or less.

The deposition chamber may comprise a chemical vapour deposition (CVD) chamber for shallow trench isolated (STI) structures.

The CVD chamber may be a high density plasma CVD (HDPCVD) chamber.

The seasoning film may have a thickness of about 2000 Å or more.

The seasoning film may have a thickness of about 3500 Å or more.

In accordance with a second aspect of the present invention there is provided a method of processing a wafer in deposition chamber, the method comprising providing a silicon based seasoning film on at least one surface inside the deposition chamber, the seasoning film having a refractive index of about 1.48 or more; and gettering metallic contamination atoms during processing of the wafer in the deposition chamber utilising the seasoning film.

The seasoning film may have a refractive index of about 1.49 or more.

The method may comprise utilising a O₂:SiH₄ gas ratio of about 1.60 or less during formation of the seasoning film.

The O₂:SiH₄ gas ratio may be about 1.50 or less.

The deposition chamber may comprise a CVD chamber for STI structures.

The CVD chamber may be a high density plasma HDPCVD chamber.

The seasoning film may have a thickness of about 2000 Å or more.

The seasoning film may have a thickness of about 3500 Å or more.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows a schematic drawing of a remote NF₃ cleaning system and CVD chamber.

FIG. 2 shows a comparison between results obtained with previous seasoning processes and seasoning processes according to example embodiments of the present invention.

FIG. 3 shows a flow-chart of a seasoning process for a deposition chamber according to an example embodiment of the present invention.

FIG. 4 shows a flow-chart of another seasoning process for a deposition chamber according to an example embodiment of the present invention.

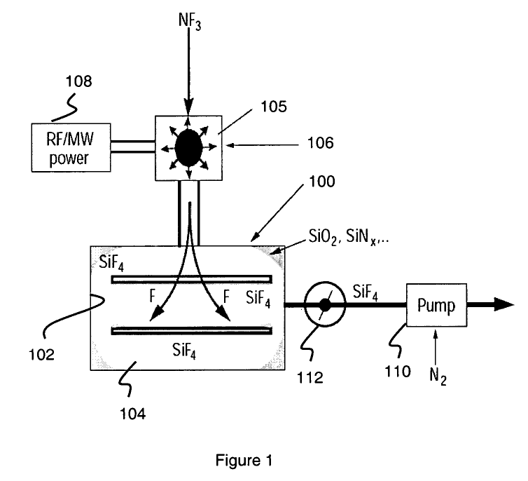

### DETAILED DESCRIPTION

During chemical vapor deposition (CVD) of silicon oxide and other layers onto the surface of a substrate, the deposition gases released inside the processing chamber may cause unwanted deposition on areas such as the walls of the processing chamber. Unless removed, this unwanted deposition is a source of particles that may interfere with subsequent processing steps and adversely effect wafer yield.

To avoid such problems, the inside surface of a chamber 100 is regularly cleaned to remove the unwanted deposition material from the chamber walls e.g. 102 and similar areas of the processing chamber 100. This procedure is performed as a standard chamber dry clean operation where an etchant gas, such as nitrogen trifluoride (NF₃), is used to remove (etch) the deposited material from the chamber walls e.g. 102 and other areas. During the dry clean operation, the chamber interior 104 is exposed to products formed by a plasma 105 of the etchant gas formed in an application tube 106, which reacts with and removes the deposited material from the chamber walls e.g. 102. Such cleaning procedures are performed between deposition steps for every wafer or every n wafers. A radio frequency/microwave (RF/MW) power supply 108 is provided for the generation of the plasma in the applicator tube 106.

However, the cleaning step can, in itself, be a source of particle accumulation. E.g. fluorine from the cleaning plasma can be absorbed and/or trapped in the chamber walls e.g. 102 and in other areas of the chamber 100 such as areas that include ceramic lining or other insulation material. The trapped fluorine can be released during subsequent processing steps (e.g., by reacting with constituents from the deposition plasma in a high density plasma CVD (HDPCVD) step) and can be absorbed in subsequently deposited silicon oxide or other layers.

To prevent such contaminated release and to provide protection against other contaminants within the chamber walls, e.g. 102, the diffusion of sodium, aluminum, and other contaminants, the CVD chamber 100 is often “seasoned” after the dry clean operation. Typically, seasoning includes depositing a thin silicon oxide layer over the chamber walls e.g. 102 before a substrate is introduced into the chamber 100 for processing.

A pump 110 is used to evacuate the chamber 100 after the cleaning step and/or the seasoning step, and during processing of wafers in the chamber 100. N₂ is fed into the pump 110 to achieve a higher foreline pressure and viscous flow conditions, thus reducing foreline backstreaming, in the example embodiment. A valve 112 is disposed between the pump 110 and the chamber 100.

In embodiments of the present invention, it has been found that reducing the O₂:SiH₄ gas ratio during post-clean seasoning of a deposition chamber can significantly reduce metallic contamination during subsequent depositions. In one example embodiment, Al contamination in HDPCVD STI processing is found to be reduced by about two orders of magnitude. It is believed that the prevention of the Al contamination is due to gettering of Al atoms in a post-clean seasoning film formed in the HDPCVD chamber, e.g. on the walls of the HDPCVD chamber, during the post-clean seasoning. It was found from an analysis of the seasoning film properties, that the refractive index was increased from about 1.446 in seasoning films resulting from previous chamber seasoning procedures, ranging from about 1.48 to 1.49 in seasoning films according to example embodiments of the present invention.

The thickness and refractive index (RI) characterization was achieved for the example embodiments by depositing a bare Si wafer in the HDPCVD chamber using the seasoning recipe step condition, and measuring the seasoning film thickness and RI (on bare Si wafer) on a KLA Tencor ASET-F5 , using a Spectroscopic Ellipsometer (SE) technique at a wavelength of 673 nm. The RI measurement was based on the Cauchy dispersion model.

In example embodiments, a high density plasma is formed in the presence of at least a microwave power, a silicon source, and an oxygen source whereby a silicon-rich oxide film is deposited over at least part of the inner surface of the HDPCVD chamber 100.

The deposited silicon oxide layer covers the chamber walls e.g. 102 reducing the likelihood that contaminates will interfere with subsequent processing steps. After deposition of the seasoning layer is complete, the chamber is used for one to n substrate deposition steps before being cleaned in another clean operation as described above and then re-seasoned.

In one example embodiment, by lowering the O₂:SiH₄ gas ratio to a range of about 1.60 during chamber seasoning, a silicon-rich oxide coating may be achieved. The refractive index was found to be about 1.4918 in that example embodiment.

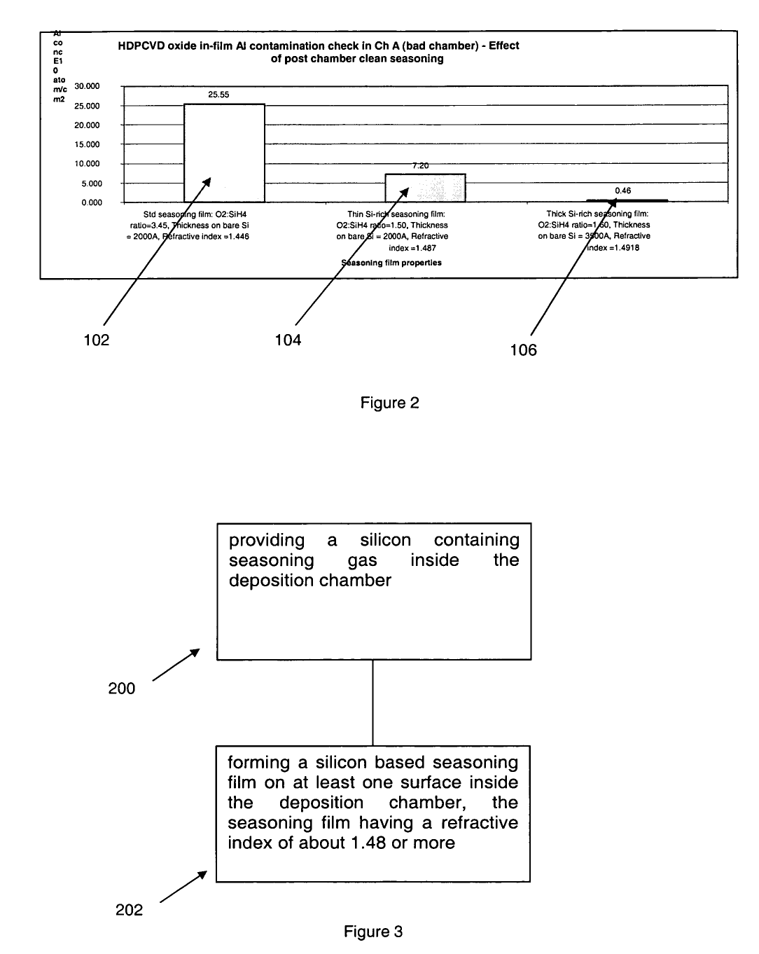

FIG. 2 shows a comparison of measured Al contamination using a previous chamber seasoning process at 302, and for two chamber seasoning processes according to example embodiments of the present invention, at 304 and 306 respectively. As can be seen from FIG. 2, the Al concentration was significantly reduced from about 25E10 atoms/cm² for the previous chamber seasoning process 302, to about 7.2E10 atoms/cm² for one example embodiment 304, and to 0.46E10 atoms/cm² for another example embodiment 306.

Compared with the previous chamber seasoning processing 302, the O₂:SiH₄ ratio was reduced from about 3.45 to about 1.50 in one example embodiment 302, and from about 3.45 to about 1.60 in another example embodiment 306.

It was further found that increasing the thickness of the silicon-rich oxide film further reduces contamination during processing of a wafer in the HDPCVD chamber for a given, reduced O₂:SiHy ratio in different embodiments.

FIG. 3 shows a flow-chart of a seasoning process for a deposition chamber in an example embodiment. At step 200, a silicon containing seasoning gas is provided inside the deposition chamber. At step 202, a silicon based seasoning film is formed on at least one surface inside the deposition chamber, the seasoning film having a refractive index of about 1.48 or more.

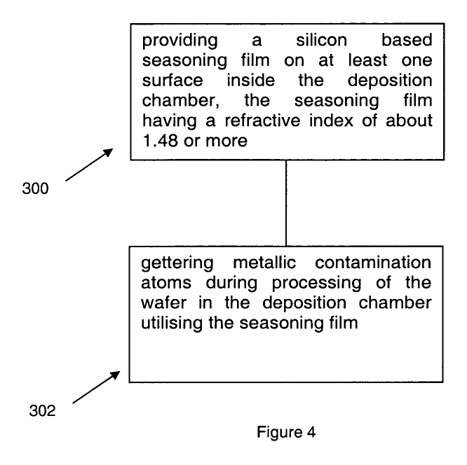

FIG. 4 shows a flow chart illustrating a method of processing a wafer in deposition chamber in an example embodiment. At step 300, a silicon based seasoning film is provided on at least one surface inside the deposition chamber, the seasoning film having a refractive index of about 1.48 or more. At step 302, metallic contamination atoms are gettered during processing of the wafer in the deposition chamber utilising the seasoning film.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, while the present invention has been described with reference to CVD processing chambers, it will be appreciated that it also applies to other deposition chambers, including for example evaporation deposition chambers.

1. A seasoning process for a deposition chamber, the process comprising:
providing a silicon-containing seasoning gas inside the deposition chamber; and
forming a silicon-based seasoning film on at least one surface inside the deposition chamber, the seasoning film having a refractive index of about 1.48 or more.

2. The method as claimed in claim 1, wherein the seasoning film has a refractive index of about 1.49 or more.

3. The method as claimed in claim 1, comprising utilising a O2:SiH4 gas ratio of about 1.60 or less during the formation of the seasoning film.

4. The method as claimed in claim 3, wherein the O2:SiH4 gas ratio is about 1.50 or less.

5. The method as claimed in claim 1, wherein the deposition chamber comprises a chemical vapour deposition (CVD) chamber for shallow trench isolated (STI) structures.

6. The method as claimed in claim 5, wherein the CVD chamber is a high density plasma CVD (HDPCVD) chamber.

7. The method as claimed in claim 1, wherein the seasoning film has a thickness of about 2000 Å or more.

8. The method as claimed in claim 7, wherein the seasoning film has a thickness of about 3500 Å or more.

9. A method of processing a wafer in deposition chamber, the method comprising
providing a silicon based seasoning film on at least one surface inside the deposition chamber, the seasoning film having a refractive index of about 1.48 or more; and
gettering metallic contamination atoms during processing of the wafer in the deposition chamber utilising the seasoning film.

10. The method as claimed in claim 9, wherein the seasoning film has a refractive index of about 1.49 or more.

11. The method as claimed in claim 9, comprising utilising a O2:SiH4 gas ratio of about 1.60 or less during formation of the seasoning film.

12. The method as claimed in claim 11, wherein the O2:SiH4 gas ratio is about 1.50 or less.

13. The method as claimed in claim 9, wherein the deposition chamber comprises a CVD chamber for STI structures.

14. The method as claimed in claim 13, wherein the CVD chamber is a high density plasma HDPCVD chamber.

15. The method as claimed in claim 9, wherein the seasoning film has a thickness of about 2000 Å or more.

16. The method as claimed in claim 15, wherein the seasoning film has a thickness of about 3500 Å or more.
